(19) United States
(12) Patent Application Publication
(10) Pub. No.: US 2025/0364453 A1
(43) Pub. Date: Nov. 27, 2025

(54) SUBSTRATE FOR POWER MODULE

(71) Applicant: MITSUBISHI HEAVY INDUSTRIES, LTD., Tokyo (JP)

(72) Inventors: Nobuki Yamashita, Tokyo (JP); Norihito Yanagita, Tokyo (JP); Takashi Masuzawa, Tokyo (JP); Masahiko Ezumi, Tokyo (JP)

(73) Assignee: MITSUBISHI HEAVY INDUSTRIES, LTD., Tokyo (JP)

(21) Appl. No.: 18/873,829

(22) PCT Filed: Feb. 8, 2023
(86) PCT No.: PCT/JP2023/004096

§ 371 Date: Dec. 11, 2024

(30) Foreign Application Priority Data
Jun. 14, 2022 (JP) 2022-096031

(51) Int. Cl. H01L 23/00

(52) U.S. Cl. CPC H01L 24/05; H01L 24/48; H01L 2224/05083; H01L 2224/05166; H01L 2224/05187; H01L 2224/48225

(57) ABSTRACT

A power module substrate according to the present disclosure comprises: an insulating plate; a plurality of surface patterns provided on the surface of the insulating plate; a power semiconductor element connected to one surface pattern among the plurality of surface patterns; an electrode unit provided on the upper surface of the power semiconductor element; and a bonding wire connected to both the electrode part and another surface pattern that is different from the one front surface pattern among the plurality of surface patterns. The electrode part comprises: a contact layer that is formed from a metal and is provided on the upper surface; a protection layer that is layered on the contact layer; and a connection layer that is formed from a metal, and is layered on the protection layer in a state where said connection layer is connected to the bonding wire. The protective layer contains a highly electrically conductive ceramic that is harder than the contact layer and the connection layer.

### TECHNICAL FIELD

The present disclosure relates to a substrate for a power module.

Priority is claimed on Japanese Patent Application No. 2022-96031, filed in Japan on Jun. 14, 2022, the content of which is incorporated herein by reference.

### BACKGROUND ART

For example, PTL 1 discloses a power semiconductor device in which a surface electrode of a power semiconductor element is formed of a plurality of different metal layers. A layer structure including the plurality of metal layers is formed of an Al layer, a Cu layer formed on the Al layer and having a Vickers hardness of 200 to 350 Hv, and a Cu layer formed on the Cu layer and having a Vickers hardness of 70 to 150 Hv. Such a layer structure reduces damage to the power semiconductor element when bonding is performed with a Cu wire.

### CITATION LIST

### Patent Literature

[PTL 1] Japanese Unexamined Patent Application Publication No. 2018-37684

### SUMMARY OF INVENTION

### Technical Problem

In recent years, in the field of power semiconductor elements, there has been an increasing trend toward higher voltages, larger currents, higher frequencies, and faster switching of power semiconductor elements in order to improve added values. Accordingly, for example, the number of bonding wires connected to the electrodes of the power semiconductor element by wire bonding may increase. Therefore, there is a demand for a technique for further reducing damage to the power semiconductor element during wire bonding.

The present disclosure has been made to solve the above problem, and an object of the present disclosure is to provide a substrate for a power module capable of further reducing damage applied to a power semiconductor element during wire bonding.

### Solution to Problem

In order to solve the above problem, a substrate for a power module according to the present disclosure includes an insulating plate, a plurality of front surface patterns disposed on a front surface of the insulating plate, a power semiconductor element connected to one front surface pattern of the plurality of front surface patterns, an electrode portion disposed on an upper surface of the power semiconductor element, and a bonding wire for connecting another front surface pattern different from the one front surface pattern among the plurality of front surface patterns and the electrode portion, in which the electrode portion includes a contact layer formed of a metal and disposed on the upper surface, a protective layer laminated on the contact layer, and a connection layer formed of a metal and laminated on the protective layer in a state of being connected to the bonding wire, and the protective layer includes a conductive ceramic having a hardness higher than that of the contact layer and the connection layer.

### Advantageous Effects of Invention

According to the present disclosure, it is possible to provide a substrate for a power module capable of further reducing damage applied to a power semiconductor element during wire bonding.

### BRIEF DESCRIPTION OF DRAWINGS

FIG. 1 is a perspective view illustrating a schematic configuration of a power conversion device according to a first embodiment of the present disclosure.

FIG. 2 is a diagram of a power module according to the first embodiment of the present disclosure as viewed from a direction of line II-II shown in FIG. 1.

FIG. 3 is a cross-sectional view taken along line III-III in FIG. 2.

FIG. 4 is an enlarged view of a main part of FIG. 3 and is a view illustrating a layer structure of an electrode portion.

FIG. 5 is a diagram illustrating a layer structure of an electrode portion when a main part in a cross-sectional view of a power module according to a second embodiment of the present disclosure is enlarged, and is a diagram corresponding to the portion illustrated in FIG. 4.

FIG. 6 is a diagram illustrating a layer structure of an electrode portion when a main part in a cross-sectional view of a power module according to a third embodiment of the present disclosure is enlarged, and is a diagram corresponding to the portion illustrated in FIG. 4.

FIG. 7A shows the results of Example 1.

FIG. 7B shows the results of Example 1.

FIG. 8 shows the results of Example 2.

FIG. 9 shows the results of Example 3.

### Description of Embodiments

Hereinafter, embodiments for implementing a power conversion device including a substrate for a power module according to the present disclosure will be described with reference to the accompanying drawings.

### First Embodiment

The power conversion device is a device that converts DC power into three-phase AC power or the like. Examples of the power conversion device of the present embodiment include an inverter used in a system of a power plant or the like and an inverter used for driving an electric motor (motor) of an electric vehicle or the like.

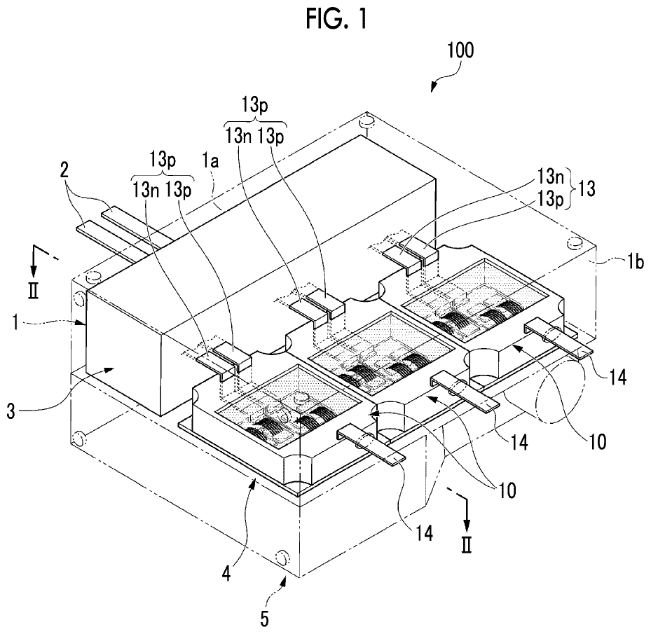

As illustrated in FIG. 1, a power conversion device 100 includes a casing 1, an external input conductor 2, a capacitor 3, a power conversion unit 4, and a cooler 5. In FIG. 1, the casing 1 and the cooler 5 are indicated by two-dot chain lines.

### Casing

The casing 1 forms an outer shell of the power conversion device 100. The casing 1 in the present embodiment is formed of a metal such as aluminum (Al), a synthetic resin, or the like. The casing 1 in the present embodiment is formed of aluminum and has a rectangular parallelepiped shape. An outer surface of the casing 1 has two side surfaces arranged back-to-back to each other.

Hereinafter, for convenience of description, of these two side surfaces, the side surface facing one side is referred to as an “input side side surface 1a”, and the side surface facing the other side is referred to as an “output side side surface 1b”. The external input conductor 2 for inputting DC power is led out from the input side side surface 1a.

### External Input Conductor

The external input conductors 2 are a pair of electrical conductors (bus bars) that supply DC power supplied from a power system outside the power conversion device 100 or from a DC power supply such as a battery to the capacitor 3. The external input conductor 2 in the present embodiment is formed of a metal including copper (Cu) or the like. One end of the external input conductor 2 is connected to the capacitor 3, and the other end of the external input conductor 2 extends, for example, in a direction intersecting the input side side surface la of the casing 1.

### Capacitor

The capacitor 3 is a smoothing capacitor for storing electric charge input from the external input conductor 2 and suppressing voltage fluctuation associated with power conversion. The DC voltage whose ripple is suppressed and smoothed by passing through the capacitor 3 is supplied (applied) to the power conversion unit 4.

### Power Conversion Unit

The power conversion unit 4 converts the voltage input from the capacitor 3. The power conversion unit 4 is accommodated in the casing 1. In order to output three-phase AC power, the power conversion unit 4 according to the present embodiment includes three power modules 10 respectively responsible for outputs for a U phase, a V phase, and a W phase. Therefore, the power conversion device 100 in the present embodiment is a three-phase inverter including three power modules 10.

### Power Module

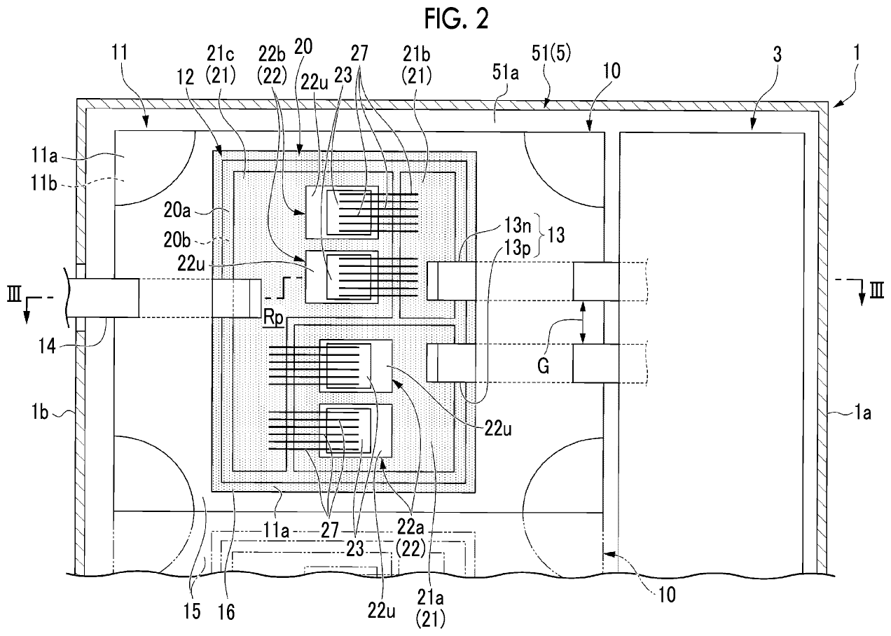

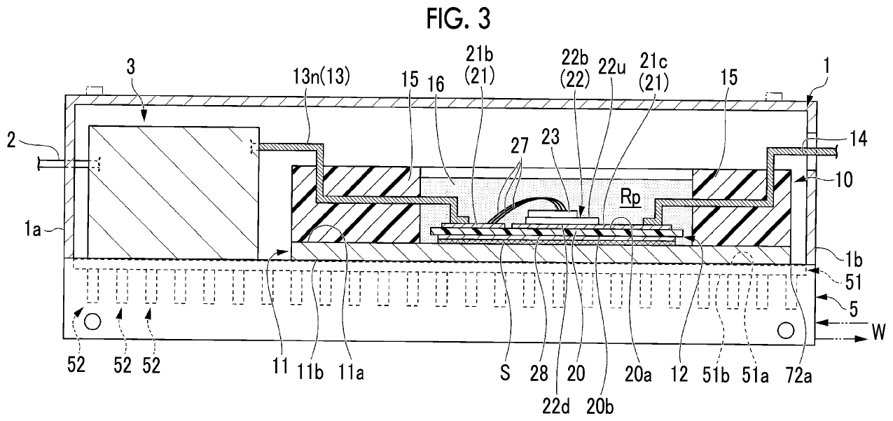

The power module 10 is a device that converts input power and outputs the converted power. As illustrated in FIGS. 2 and 3, the power module 10 includes a base plate 11, a substrate 12 for a power module, a main terminal portion 13, an output terminal portion 14, a reinforcing portion 15, and a sealing portion 16.

### Base Plate

The base plate 11 is a member having a flat plate shape. The base plate 11 has a first surface 11a and a second surface 11b located on a back side of the first surface 11a. That is, the first surface 11a and the second surface 11b of the base plate 11 are back-to-back in a state of being parallel to each other. The second surface 11b of the base plate 11 is fixed to the cooler 5 via a bonding material or the like (not shown). For example, copper is adopted for the base plate 11 in the present embodiment. The metal such as aluminum may be adopted for the base plate 11.

### Substrate for Power Module

The substrate 12 for a power module includes an insulating plate 20, a front surface pattern 21, a power semiconductor element 22, an electrode portion 23, a bonding wire 27, and a back surface pattern 28.

### Insulating Plate

The insulating plate 20 has a flat plate shape. The insulating plate 20 has a front surface 20a and a back surface 20b located on a back side of the front surface 20a. The front surface 20a and the back surface 20b of the insulating plate 20 are back-to-back in a state of being parallel to each other.

The insulating plate 20 in the present embodiment is formed of, for example, an insulating material such as ceramic. As the insulating material for forming the insulating plate 20, paper phenol, paper epoxy, glass composite, glass epoxy, glass polyimide, fluororesin, or the like can be adopted in addition to ceramic.

### Front Surface Pattern

The front surface pattern 21 is a pattern of copper foil (Cu) or the like formed on the front surface 20a of the insulating plate 20 and extending in a planar shape. The front surface pattern 21 is formed by, for example, being fixed to the front surface 20a of the insulating plate 20 by adhesion or the like and then being subjected to etching or the like.

A plurality of the front surface patterns 21 are disposed on the front surface 20a of the insulating plate 20. The plurality of front surface patterns 21 are disposed adjacent to each other with a gap therebetween in a direction in which the insulating plate 20 extends. In the present embodiment, a case where three front surface patterns 21 are disposed on the front surface 20a of the insulating plate 20 will be described as an example. Hereinafter, for convenience of description, these three front surface patterns 21 are referred to as a first front surface pattern 21a, a second front surface pattern 21b, and a third front surface pattern 21c.

The first front surface pattern 21a and the second front surface pattern 21b are patterns for exchanging input and output of DC power with the capacitor 3, and correspond to an inlet portion or an outlet portion of a loop between P and N formed in the front surface pattern 21.

The main terminal portion 13 connected to the capacitor 3 is connected to the first front surface pattern 21a and the second front surface pattern 21b in the present embodiment. The output terminal portion 14 for outputting the AC current converted by the power semiconductor element 22 to a load (not shown) provided outside the power conversion device 100 is connected to the third front surface pattern 21c.

### Power Semiconductor Element

The power semiconductor element 22 is a circuit element that converts power by means of a switching operation of turning on and off a voltage or a current. The power semiconductor element 22 is, for example, a switching element such as an IGBT or a MOSFET. The power semiconductor element 22 is formed of, for example, a Si-based single crystal or a SiC-based single crystal having hardness higher than that of the Si-based single crystal.

In the present embodiment, as an example, a MOSFET is applied to the power semiconductor, and four power semiconductor elements 22 are connected to the front surface pattern 21 of the substrate 12 for a power module. When an IGBT is used as the power semiconductor element 22, it is necessary to arrange in parallel a diode that causes a current to flow in a direction opposite to that of the IGBT.

The four power semiconductor elements 22 in the present embodiment include two first power semiconductor elements 22a and two second power semiconductor elements 22b. The first power semiconductor element 22a is connected to the first front surface pattern 21a. The second power semiconductor element 22b is connected to the third front surface pattern 21c.

When the power semiconductor element 22 is a MOSFET, the power semiconductor element 22 includes a lower surface 22d (see FIG. 3) on which an input terminal (not shown) corresponding to a drain is formed, an upper surface 22u on which an output terminal (not shown) corresponding to a source is formed, and a gate (not shown) corresponding to a control signal input terminal for controlling switching of the power semiconductor element 22.

The lower surface 22d of the power semiconductor element 22 is electrically connected to the front surface pattern 21 via a bonding material S. A lower surface 22d of the first power semiconductor element 22a is connected to the first front surface pattern 21a. A lower surface 22d of the second power semiconductor element 22b is connected to the third front surface pattern 21c. As the bonding material S in the present specification, for example, solder, a sintered material (powder of metal or the like), or the like can be adopted.

A control signal generated by a gate driving substrate or the like (not shown) provided outside the substrate 12 for a power module is input to the power semiconductor element 22 through the gate. The power semiconductor element 22 performs switching in accordance with the control signal. When the power semiconductor element 22 is an IGBT, the power semiconductor element 22 has a lower surface 22d corresponding to a collector, an upper surface 22u corresponding to an emitter, and a gate corresponding to a control signal input terminal.

### Electrode Portion

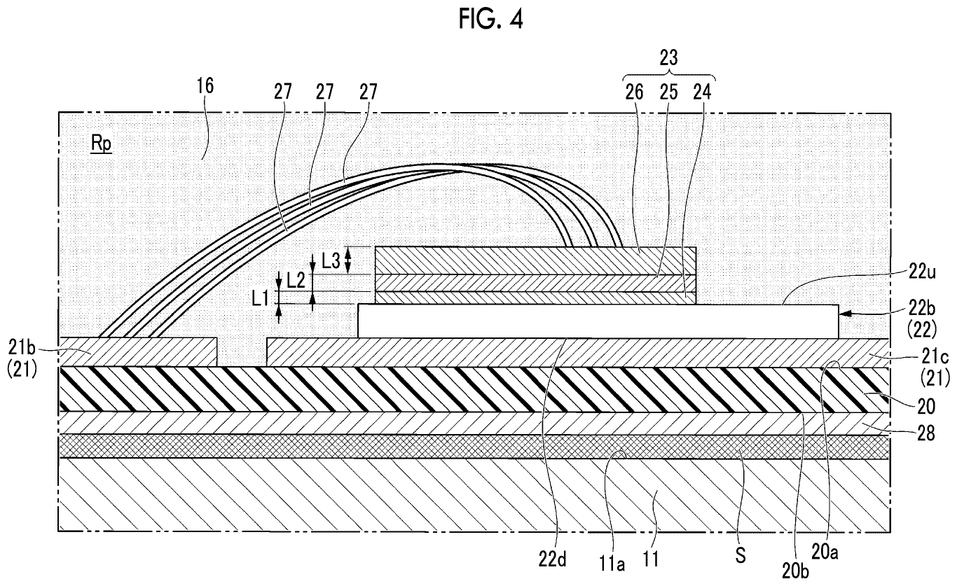

The electrode portion 23 is disposed on the upper surface 22u of the power semiconductor element 22. The electrode portion 23 corresponds to an electrode portion in the power semiconductor element 22. The electrode portion 23 in the present embodiment has a three-layer structure. As illustrated in FIG. 4, the electrode portion 23 includes a contact layer 24, a protective layer 25, and a connection layer 26.

The contact layer 24 is disposed on the upper surface 22u, and is connected to the output terminal in a state of being integrated with the output terminal formed on the upper surface 22u. The contact layer 24 is formed of a metal. Any one of Ni, Al, and Cr can be adopted as the metal forming the contact layer 24 in the present embodiment. A thickness L1 of the contact layer 24 is 0.05 to 0.5 μm. The contact layer 24 is formed on the upper surface 22u of the power semiconductor element 22 by, for example, a sputtering method.

The protective layer 25 is a conductive material laminated on the contact layer 24. That is, the protective layer 25 is formed on the contact layer 24 in a state of being integrated with the contact layer 24. The protective layer 25 is formed of a conductive ceramic. As the conductive ceramic forming the protective layer 25 in the present embodiment, any one of TiB₂ (titanium diboride), ZrB₂ (zirconium diboride), HfB₂ (hafnium diboride), TiSi₂ (titanium disilicide), and WSi₂ (tungsten disilicide) can be adopted. A thickness L2 of the protective layer 25 is 0.5 to 2 μm. The protective layer 25 is formed on the contact layer 24 by, for example, a sputtering method.

The connection layer 26 is laminated on the protective layer 25. That is, the connection layer 26 is formed on the protective layer 25 in a state of being integrated with the protective layer 25. The connection layer 26 is formed of metal. As the metal forming the connection layer 26 in the present embodiment, copper, an alloy containing copper, or the like can be adopted. A thickness L3 of the connection layer 26 is 10 to 20 μm. The connection layer 26 is formed on the protective layer 25 by, for example, a sputtering method.

Here, the hardness of the conductive ceramic forming the protective layer 25 is higher than the hardness of the metal forming the contact layer 24 and the connection layer 26. Specifically, the conductive ceramic forming the protective layer 25 has a Vickers hardness 10 times or more that of the metal forming the contact layer 24 and the connection layer 26. The thermal conductivity of the conductive ceramic forming the protective layer 25 is lower than the thermal conductivity of the metal forming the contact layer 24 and the connection layer 26.

The Vickers hardness of TiB₂ is, for example, 32 to 34 GPa. The Vickers hardness of ZrB₂ is, for example, 21 to 23 GPa. The Vickers hardness of HfB₂ is, for example, 27 to 29 GPa. The Vickers hardness of TiSi₂ is, for example, 9 to 11 GPa. The Vickers hardness of WSi₂ is, for example, 9 to 11 GPa.

### Bonding Wire

As illustrated in FIGS. 2 to 4, bonding wire 27 is a conductive wire connecting the front surface pattern 21 and the electrode portion 23 disposed on the upper surface 22u of the power semiconductor element 22. The bonding wire 27 in the present embodiment is formed of a metal containing copper or the like, and has a diameter of, for example, 200 to 400 μm.

One end of the bonding wire 27 is connected to the connection layer 26 in the electrode portion 23. The other end of the bonding wire 27 is connected to the front surface pattern 21. In the present embodiment, a plurality of bonding wires 27 connect the connection layer 26 and the front surface pattern 21.

Specifically, as illustrated in FIG. 2, six bonding wires 27 connect the connection layer 26 of the electrode portion 23 disposed on the upper surface 22u of the first power semiconductor element 22a and the third front surface pattern 21c. As illustrated in FIGS. 2 to 4, six bonding wires 27 connect the connection layer 26 of the electrode portion 23 disposed on the upper surface 22u of the second power semiconductor element 22b and the second front surface pattern 21b. That is, the front surface patterns 21 disposed on the front surface 20a of the insulating plate 20 are electrically connected to each other by the bonding wires 27.

The one end and the other end of the bonding wire 27 are integrally connected to the connection layer 26 in the electrode portion 23 and the front surface pattern 21, respectively, by wire bonding in which ultrasonic waves or the like are applied from the outside.

DC power is input to the first power semiconductor element 22a through the first front surface pattern 21a, and DC power is input to the second power semiconductor element 22b through the second front surface pattern 21b and the bonding wire 27 connecting the second front surface pattern 21b and the second power semiconductor element 22b. When the first power semiconductor element 22a and the second power semiconductor element 22b perform a switching operation, the DC power is converted into AC power and output to the third front surface pattern 21c through the electrode portion 23 and the bonding wire 27.

### Back Surface Pattern

The back surface pattern 28 is a pattern of copper foil or the like formed on the back surface 20b of the insulating plate 20 and extending in a planar shape. The back surface pattern 28 is fixed to the center of the first surface 11a of the base plate 11 via the bonding material S. The back surface pattern 28 is formed by, for example, being fixed to the back surface 20b of the insulating plate 20 by adhesion or the like and then being subjected to etching or the like.

### Main Terminal Portion

The main terminal portion 13 is an electrical conductor (bus bar) that exchanges DC power between the capacitor 3 and the substrate 12 for a power module. The main terminal portion 13 is formed of a metal including copper or the like. The main terminal portion 13 has a P terminal 13p as a positive electrode and an N terminal 13n as a negative electrode.

The P terminal 13p and the N terminal 13n are arranged side by side via a gap G as a spatial distance (insulation distance). The P terminal 13p connects a positive electrode (not shown) of the capacitor 3 and the first front surface pattern 21a of the substrate 12 for a power module. The N terminal 13n connects a negative electrode (not shown) of the capacitor 3 and the second front surface pattern 21b of the substrate 12 for a power module.

### Output Terminal Portion

The output terminal portion 14 is an electrical conductor (bus bar) for outputting the AC power converted by the power semiconductor element 22 to the outside of the power conversion device 100. The output terminal portion 14 is formed of a metal including copper or the like. One end of the output terminal portion 14 is connected to the third front surface pattern 21c of the substrate 12 for a power module. As illustrated in FIG. 1, for example, the other end of the output terminal portion 14 extends outward beyond the output side side surface 1b of the casing 1. To the other end of the output terminal portion 14, for example, a wire (not shown) for power output connected to a load of a motor or the like (AC rotating electric machine) is connected.

### Reinforcing Portion

As illustrated in FIGS. 2 and 3, the reinforcing portion 15 is a member that mechanically reinforces the main terminal portion 13 and the output terminal portion 14 in a state of being fixed to the first surface 11a of the base plate 11. The reinforcing portion 15 is formed of, for example, a synthetic resin material (insulating material) or the like. For example, PPS (polyphenylene sulfide) can be adopted as the material forming the reinforcing portion 15 in the present embodiment. A synthetic resin material other than PPS may be adopted for the reinforcing portion 15. The reinforcing portion 15 is fixed to the first surface 11a of the base plate 11 by, for example, an adhesive agent.

The reinforcing portion 15 surrounds the substrate 12 for a power module from the outside in a state of covering the P terminal 13p and the N terminal 13n of the main terminal portion 13 and the output terminal portion 14 from the outside. The reinforcing portion 15 forms a case surrounding the substrate 12 for a power module from the periphery in a direction along the front surface 20a of the base plate 11. Therefore, the reinforcing portion 15 defines a space in which the substrate 12 for a power module is accommodated together with the base plate 11. In the present embodiment, for convenience of description, the space in which the substrate 12 for a power module is accommodated is referred to as a “potting space Rp”.

### Sealing Portion

The sealing portion 16 is a sealing member disposed in the potting space Rp. The sealing portion 16 in the drawings is shown with hatching for convenience of illustration. The potting space Rp is filled with a liquid potting material from the outside (potting) to seal the members exposed in the potting space Rp. The sealing portion 16 is formed by applying a predetermined temperature and time to the potting material filled in the potting space Rp and curing the potting material. The sealing portion 16 formed by curing the potting material electrically insulates the members in the potting space Rp from each other and electrically insulates the members from the space outside the power module 10.

As the potting material in the present embodiment, for example, silicone gel or epoxy resin can be used. The potting material may be a synthetic resin other than silicone gel and epoxy resin. The sealing portion 16 in the potting space Rp is disposed so as to cover the surfaces of the substrate 12 for a power module, the main terminal portion 13, and the output terminal portion 14.

### Cooler

As illustrated in FIG. 1, the cooler 5 is a device that mainly cools the power module 10 of the power conversion unit 4. The cooler 5 is provided so as to be stacked on the casing 1, and is fixed to and integrated with the casing 1. As illustrated in FIG. 3, the cooler 5 includes a base portion 51 and heat dissipation fins 52. In FIG. 3, the base portion 51 and the heat dissipation fins 52 are indicated by dotted lines.

The base portion 51 has a plate shape. The base portion 51 has a bonding surface 51a bonded to the second surface 11b of the base plate 11 in the power module 10 via the bonding material S, and a heat dissipation surface 51b facing an opposite side to the bonding surface 51a.

The bonding surface 51a and the heat dissipation surface 51b are back-to-back and parallel with each other. The heat dissipation fins 52 are columnar members disposed in plurality on the heat dissipation surface 51b of the base portion 51. Each heat dissipation fin 52 protrudes from the heat dissipation surface 51b to a side opposite to the power module 10 with the base portion 51 as the center.

For example, a liquid refrigerant W such as water is introduced into the cooler 5 from the outside. The heat dissipation surface 51b of the base portion 51 and the heat dissipation fins 52 are cooled by coming into contact with the liquid refrigerant W introduced from the outside. The liquid refrigerant W is heated by heat exchange with heat conducted from the power module 10 to the base portion 51 and the heat dissipation fins 52, and simultaneously cools the power module 10.

### Operations and Effects

When the bonding wire 27 is connected to the electrode portion 23 by wire bonding using ultrasonic waves, heat and pressure generated by the ultrasonic waves are directed from the electrode portion 23 to the power semiconductor element 22.

In the configuration of the above embodiment, the protective layer 25 formed of the conductive ceramic having a hardness higher than that of the metal forming the contact layer 24 and the connection layer 26 is interposed between the contact layer 24 and the connection layer 26. Accordingly, when a pressure generated by the ultrasonic wave is applied to the connection layer 26 of the electrode portion 23, the pressure is absorbed by the protective layer 25. That is, the protective layer 25 suppresses transmission of pressure to the contact layer 24 during wire bonding.

In addition, since the thermal conductivity of the protective layer 25 is lower than the thermal conductivity of the contact layer 24 and the connection layer 26, it is possible to further suppress heat conduction from the connection layer 26 to the contact layer 24, for example, compared to a case where the protective layer 25 is formed of a metal.

Therefore, damage to the power semiconductor element 22 during wire bonding is reduced. As a result, the occurrence of abnormalities such as cracks and fissures in the power semiconductor element 22 can be suppressed.

In the above configuration, the contact layer 24 is formed with a thickness L1 of 0.05 to 0.5 μm, and the protective layer 25 is formed with a thickness L2 of 0.5 to 2 μm. Accordingly, it is possible to suppress the occurrence of deformation such as distortion or bending in each layer while ensuring conductivity between the power semiconductor element 22 and the bonding wire 27.

### Second Embodiment

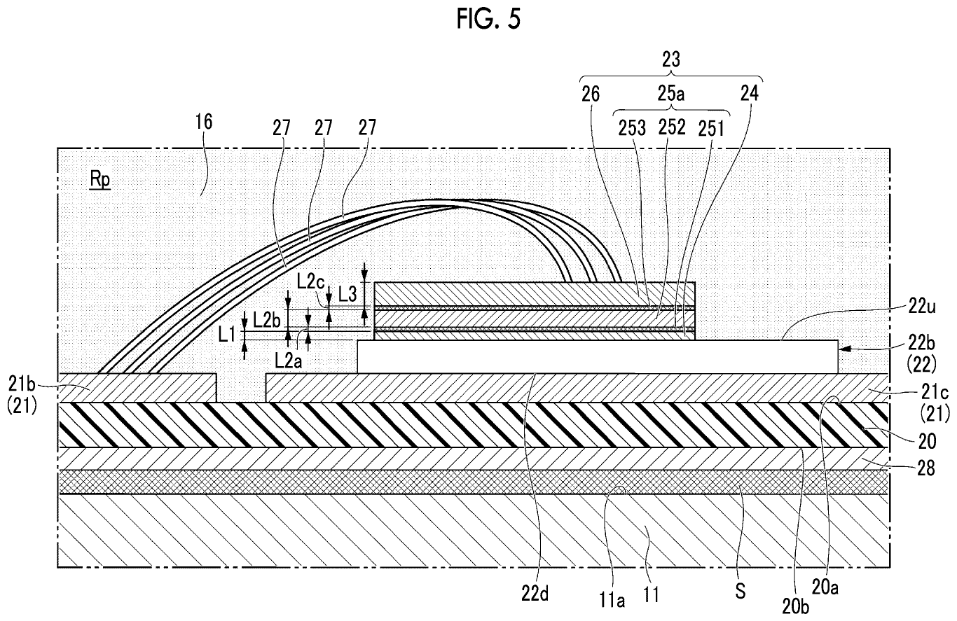

Next, a second embodiment of the power conversion device 100 according to the present disclosure will be described with reference to FIG. 5. In the second embodiment described below, the same components as those in the first embodiment are denoted by the same reference numerals in the drawings, and description thereof will be omitted. In the second embodiment, the configuration of the electrode portion 23 in the substrate 12 for a power module is different from the configuration of the electrode portion 23 described in the first embodiment.

### Electrode Portion

The electrode portion 23 in the present embodiment has a five-layer structure. The electrode portion 23 includes a contact layer 24, a protective layer 25a formed in three layers, and a connection layer 26. The protective layer 25a includes a first metal layer 251, a main body layer 252, and a second metal layer 253.

The first metal layer 251 is formed on the contact layer 24 in a state of being integrated with the contact layer 24. The first metal layer 251 is formed of a metal containing Ti (titanium). A thickness L2a of the first metal layer 251 is 0.1 to 0.5 μm. The first metal layer 251 is formed on the contact layer 24 by, for example, a sputtering method.

Here, since the first metal layer 251 is formed of a metal, the bonding force between the first metal layer 251 and the contact layer 24 is larger than the bonding force between the main body layer 252 and the contact layer 24 in a case where the first metal layer 251 is not interposed. Further, since the first metal layer 251 is formed of a metal containing Ti, the bonding force between the first metal layer 251 and the main body layer 252 is larger than, for example, the bonding force between a metal other than Ti and the main body layer 252. In other words, the combination of the first metal layer 251 and the main body layer 252 has a higher affinity than the combination of the metal other than Ti and the main body layer 252.

The main body layer 252 is laminated on the first metal layer 251. That is, the main body layer 252 is formed on the first metal layer 251 in a state of being integrated with the first metal layer 251. The main body layer 252 is formed of a conductive ceramic. Any one of TiB₂, ZrB₂, HfB₂, TiSi₂, and WSi₂ can be adopted as the conductive ceramic forming the main body layer 252 in the present embodiment. A thickness L2b of the main body layer 252 is 0.5 to 2 μm. The main body layer 252 is formed on the first metal layer 251 by, for example, a sputtering method.

The second metal layer 253 is laminated on the main body layer 252. That is, the second metal layer 253 is formed on the main body layer 252 in a state of being integrated with the main body layer 252. The second metal layer 253 is formed of a metal containing Ti. A thickness L2c of the second metal layer 253 is 0.1 to 0.5 μm. The second metal layer 253 is formed on the main body layer 252 by, for example, a sputtering method.

Here, since the second metal layer 253 is formed of a metal, the bonding force between the second metal layer 253 and the connection layer 26 is larger than the bonding force between the main body layer 252 and the connection layer 26 in a case where the second metal layer 253 is not interposed. Further, since the second metal layer 253 is formed of a metal containing Ti, the bonding force between the second metal layer 253 and the main body layer 252 is larger than, for example, the bonding force between a metal other than Ti and the main body layer 252. In other words, the combination of the second metal layer 253 and the main body layer 252 has a higher affinity than the combination of the metal other than Ti and the main body layer 252.

The connection layer 26 is laminated on the second metal layer 253. That is, the connection layer 26 is formed on the second metal layer 253 in a state of being integrated with the second metal layer 253.

### Operations and Effects

According to the configuration of the second embodiment, when the pressure generated by the ultrasonic wave is applied to the connection layer 26 of the electrode portion 23, the pressure is absorbed by the second metal layer 253. That is, the second metal layer 253 suppresses transmission of pressure to the main body layer 252 during wire bonding. The pressure transmitted from the main body layer 252 toward the power semiconductor element 22 is absorbed by the first metal layer 251. That is, the first metal layer 251 suppresses transmission of pressure to the power semiconductor element 22 via the contact layer 24 during wire bonding.

Therefore, damage to the main body layer 252 and the power semiconductor element 22 at the time of wire bonding can be further reduced. As a result, it is possible to suppress the occurrence of abnormalities such as peeling and cracking in the electrode portion 23 and to suppress the occurrence of abnormalities such as cracks and fissures in the power semiconductor element 22.

In the configuration of the second embodiment, the first metal layer 251 and the second metal layer 253 are formed with thicknesses L2a and L2c of 0.1 to 0.5 μm, and the main body layer 252 is formed with a thickness L2b of 0.5 to 2 μm. Accordingly, it is possible to suppress the occurrence of deformation such as distortion or bending in each layer while ensuring conductivity between the power semiconductor element 22 and the bonding wire 27.

### Third Embodiment

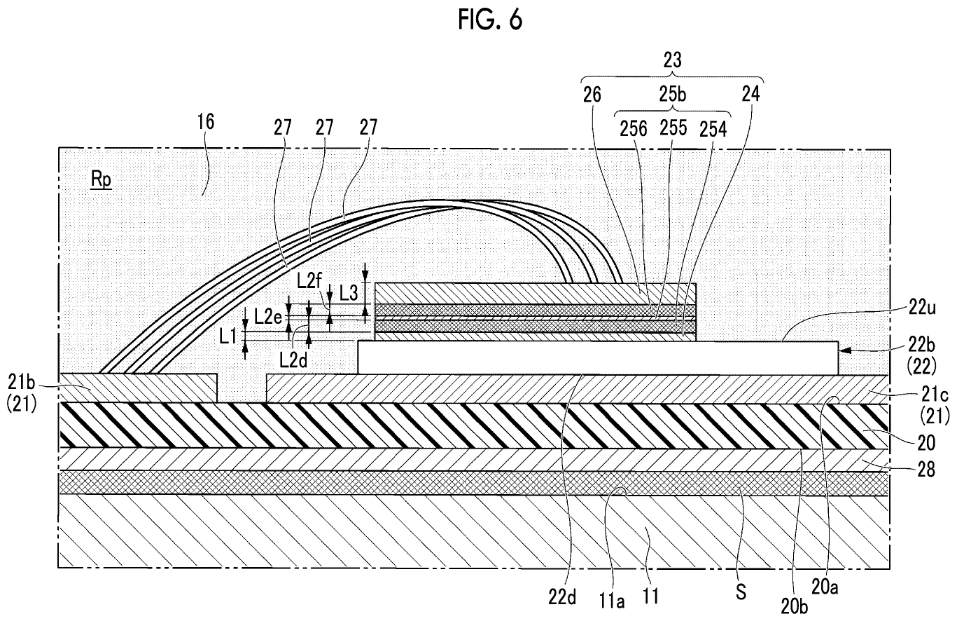

Next, a third embodiment of the power conversion device 100 according to the present disclosure will be described with reference to FIG. 6. In the third embodiment described below, the same reference numerals are given to the same components as those in the first embodiment, and the description thereof will be omitted. In the third embodiment, the configuration of the electrode portion 23 in the substrate 12 for a power module is different from the configuration of the electrode portion 23 described in the first embodiment.

### Electrode Portion

The electrode portion 23 in the present embodiment has a five-layer structure. The electrode portion 23 includes a contact layer 24, a protective layer 25b formed in three layers, and a connection layer 26. The protective layer 25b includes a first protective layer 254, a metal layer 255, and a second protective layer 256.

The first protective layer 254 is a conductive material laminated on the contact layer 24. That is, the first protective layer 254 is formed on the contact layer 24 in a state of being integrated with the contact layer 24. The first protective layer 254 is formed of a conductive ceramic. Any one of TiB₂, ZrB₂, HfB₂, TiSi₂, and WSi₂ can be adopted as the conductive ceramic forming the first protective layer 254 in the present embodiment. A thickness L2d of the first protective layer 254 is 0.5 to 2 μm. The first protective layer 254 is formed on the contact layer 24 by, for example, a sputtering method.

The metal layer 255 is laminated on the first protective layer 254. That is, the metal layer 255 is formed on the first protective layer 254 in a state of being integrated with the first protective layer 254. The metal layer 255 is formed of a metal containing Ti. A thickness L2e of the metal layer 255 is 0.1 to 0.5 μm. The metal layer 255 is formed on the first protective layer 254 by, for example, a sputtering method.

The second protective layer 256 is a conductive material laminated on the metal layer 255. That is, the second protective layer 256 is formed on the metal layer 255 in a state of being integrated with the metal layer 255. The second protective layer 256 is formed of a conductive ceramic. Any one of TiB₂, ZrB₂, HfB₂, TiSi₂, and WSi₂ can be adopted as the conductive ceramic forming the second protective layer 256 in the present embodiment. A thickness L2f of the second protective layer 256 is 0.5 to 2 μm. The second protective layer 256 is formed on the metal layer 255 by, for example, a sputtering method.

The connection layer 26 is laminated on the second protective layer 256. That is, the connection layer 26 is formed on the second protective layer 256 in a state of being integrated with the second protective layer 256.

### Operations and Effects

According to the configuration of the third embodiment, when the pressure generated by the ultrasonic waves is applied to the connection layer 26 of the electrode portion 23, the pressure is absorbed by the second protective layer 256 and the metal layer 255. That is, the second protective layer 256 and the metal layer 255 suppress transmission of pressure to the first protective layer 254 during wire bonding.

In addition, the first protective layer 254 and the second protective layer 256 formed of a conductive ceramic are laminated with the metal layer 255 formed of a metal containing Ti interposed therebetween. Accordingly, for example, compared to a case where the protective layer 25b is a single layer, it is possible to further increase the thickness of the protective layer 25b while suppressing the occurrence of deformation such as distortion or bending in the protective layer 25b. Therefore, damage to the power semiconductor element 22 during wire bonding can be further reduced.

### Other Embodiments

Although the embodiments of the present disclosure have been described in detail with reference to the drawings, specific configurations are not limited to the configurations of the embodiments, and additions, omissions, substitutions, and other modifications of the configurations can be made without departing from the gist of the present disclosure.

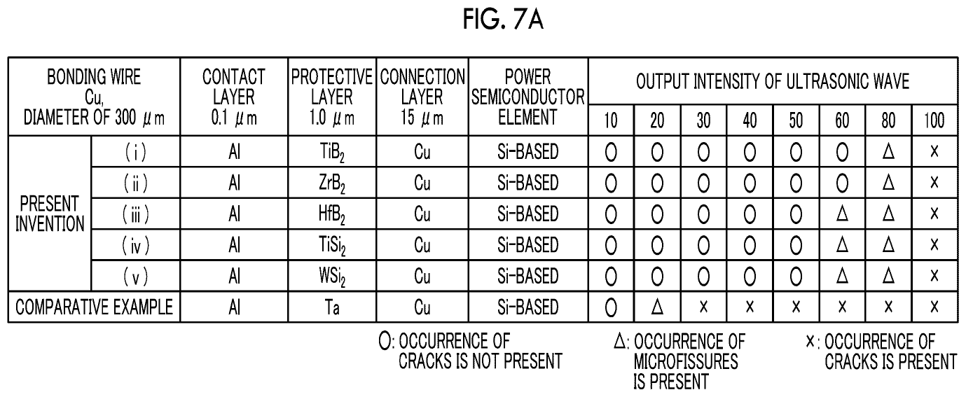

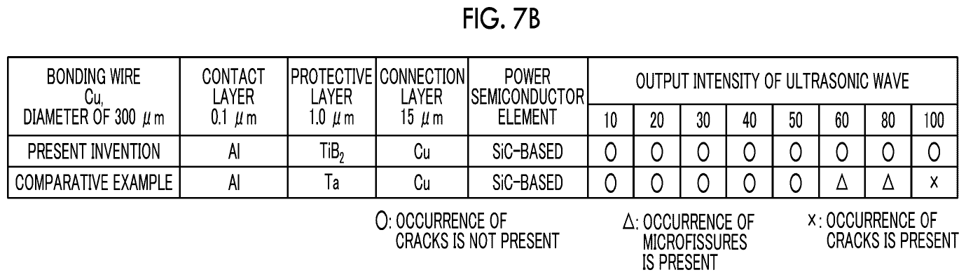

Hereinafter, results of evaluation experiments (Examples 1 to 3) for facilitating understanding of the operations and effects described in each embodiment are shown in FIGS. 7A to 9 as examples. FIGS. 7A to 9 show the presence or absence of the occurrence of cracks or fissures (microfissures) on the surface of the power semiconductor element 22 when the output intensity of the ultrasonic wave used at the time of wire bonding is changed in eight stages in the range of 10 to 100. “10” in the output intensity of the ultrasonic wave indicates a predetermined output intensity defined in advance. When manufacturing the power module 10 in the above embodiment, for example, “30” is adopted as the output intensity of the ultrasonic wave. The presence or absence of the occurrence of cracks or fissures on the surface of the power semiconductor element 22 is determined by observing the surface of the power semiconductor element 22 with, for example, a scanning electron microscope (SEM) and comparing the surface with, for example, a limit sample.

In this evaluation experiment, the bonding wire 27 is formed of copper and has a diameter of 300 μm. The contact layer 24 is formed of aluminum and has a thickness L1 of 0.1 μm. The connection layer 26 is formed of copper and has a thickness L3 of 15 μm. Note that the diameter of the bonding wire 27, the thickness L1 of the contact layer 24, and the thickness L3 of the connection layer 26 shown here indicate nominal values, and slight manufacturing errors and design tolerances are allowed.

“Example 1”

FIG. 7A shows a case where the power semiconductor element 22 is formed of a Si-based single crystal. Rows (i) to (v) in “present invention” in FIG. 7A show results after wire bonding in the configuration described in the first embodiment, and a row of “comparative example” in FIG. 7A shows results after wire bonding in a configuration in which the conductive ceramic is not used for the protective layer 25. The protective layer 25 in the “present invention” in FIG. 7A is formed of each of TiB₂, ZrB₂, HfB₂, TiSi₂, and WSi₂, and is formed with a thickness L2 of 1.0 μm in each case. In the “comparative example” in FIG. 7A, the protective layer 25 is formed of a metal containing Ta (tantalum) and has a thickness of 1.0 μm. The thickness L2 of the protective layer 25 shown here indicates a nominal value, and a slight error in manufacturing and a tolerance in design are allowed.

FIG. 7B shows a case where the power semiconductor element 22 is formed of a SiC-based single crystal. The row of “present invention” in FIG. 7B shows the results after wire bonding with the configuration described in the first embodiment, and the row of “comparative example” in FIG. 7B shows the results after wire bonding with a configuration in which conductive ceramic is not used for the protective layer 25. The protective layer 25 in the “present invention” in FIG. 7B is formed of TiB₂ with a thickness L2 of 1.0 μm. In “comparative example” in FIG. 7B, the protective layer 25 is formed of a metal containing Ta (tantalum) and has a thickness of 1.0 μm. The thickness L2 of the protective layer 25 shown here indicates a nominal value, and a slight error in manufacturing and a tolerance in design are allowed.

It can be understood from FIGS. 7A and 7B showing the operation and effect of the configuration of the first embodiment that generation of cracks and fissures in the power semiconductor element 22 is suppressed as compared with the “comparative example”.

“Example 2”

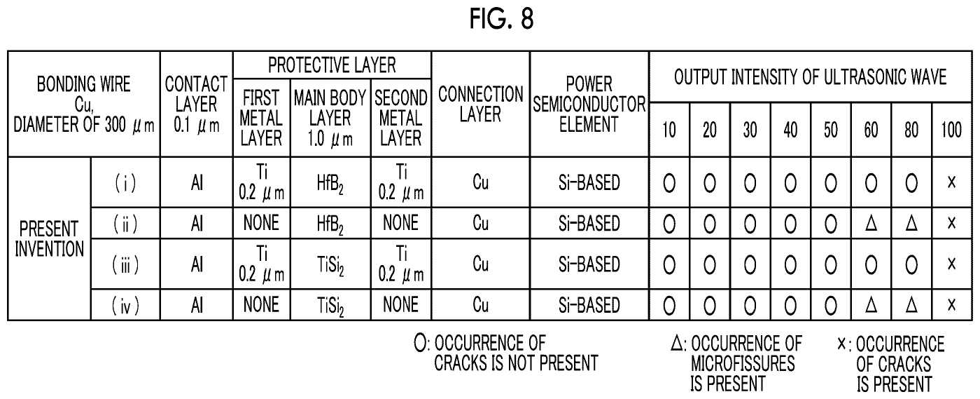

FIG. 8 shows a case where the power semiconductor element 22 is formed of a Si-based single crystal. Rows (i) and (iii) in “present invention” in FIG. 8 show results after wire bonding in the configuration described in the second embodiment. The first metal layer 251 and the second metal layer 253 in (i) and (iii) of the “present invention” in FIG. 8 are formed of Ti and have thicknesses L2a and L2c of 0.2 μm, respectively. The main body layer 252 in (i) of the “present invention” in FIG. 8 is formed of HfB₂ with a thickness L2b of 1.0 μm. The main body layer 252 in (iii) of the “present invention” in FIG. 8 is formed of TiSi₂ with a thickness L2b of 1.0 μm. The thickness L2a of the first metal layer 251, the thickness L2c of the second metal layer 253, and the thickness L2b of the main body layer 252 shown here indicate nominal values, and slight errors in manufacturing and tolerances in design are allowed.

The row (ii) in “present invention” in FIG. 8 shows the results shown in the row (iii) in “present invention” in FIG. 7A. The row (iv) in “present invention” in FIG. 8 shows the results shown in the row (iv) in “present invention” in FIG. 7A. In this case, the “main body layer” in FIG. 8 may be read as the “protective layer” in FIG. 7A.

From FIG. 8 showing the operation and effect achieved by the configuration of the second embodiment, it can be understood that the occurrence of cracks and fissures in the power semiconductor element 22 is suppressed as compared with the “comparative example”.

“Example 3”

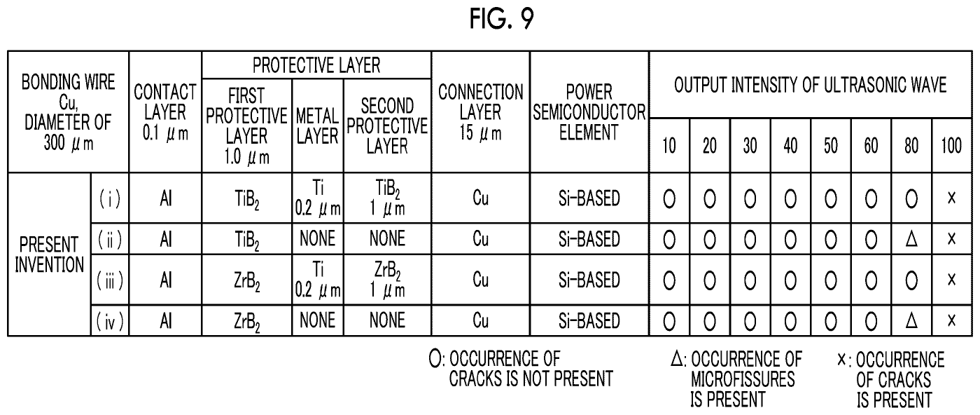

FIG. 9 shows a case where the power semiconductor element 22 is formed of a Si-based single crystal. Rows (i) and (iii) in “present invention” in FIG. 9 show results after wire bonding in the configuration described in the third embodiment. The first protective layer 254 and the second protective layer 256 in (i) of the “present invention” in FIG. 9 are formed of TiB₂ and have thicknesses L2d and L2f of 1.0 μm, respectively. The first protective layer 254 and the second protective layer 256 in (iii) of the “present invention” in FIG. 9 are formed of ZrB₂, and are formed with thicknesses L2d and L2f of 1.0 μm, respectively. The metal layer 255 in (i) and (iii) of the “present invention” in FIG. 9 is formed of Ti with a thickness L2e of 0.2 μm. The thickness L2d of the first protective layer 254, the thickness L2f of the second protective layer 256, and the thickness L2e of the metal layer 255 shown here indicate nominal values, and slight errors in manufacturing and tolerances in design are allowed.

The row (ii) in “present invention” in FIG. 9 shows the results shown in the row (i) in “present invention” in FIG. 7A. The row (iv) in “present invention” in FIG. 9 shows the results shown in the row (ii) in “present invention” in FIG. 7A. In this case, the “first protective layer” in FIG. 9 may be read as the “protective layer” in FIG. 7A

From FIG. 9 showing the operation and effect achieved by the configuration of the third embodiment, it can be understood that the occurrence of cracks and fissures in the power semiconductor element 22 is suppressed as compared with the “comparative example”.

In the embodiment, the inverter has been described as an example of the power conversion device 100, but the power conversion device 100 is not limited to the inverter. The power conversion device 100 may be, for example, a device that performs power conversion by means of the power semiconductor element 22, such as a converter or a combination of an inverter and a converter. When the power conversion device 100 is a converter, the power conversion device 100 may be configured such that an AC voltage is input from an external input power supply or the like (not shown) to the output terminal portion 14, the power semiconductor element 22 converts the AC voltage into a DC voltage, and the DC voltage from the power semiconductor element 22 is output from the input portion.

### Supplementary Notes

The substrate for a power module described in the embodiment is understood as follows, for example.
(1) A substrate 12 for a power module according to a first aspect includes an insulating plate 20, a plurality of front surface patterns 21 disposed on a front surface 20a of the insulating plate 20, a power semiconductor element 22 connected to one front surface pattern 21 among the plurality of front surface patterns 21, an electrode portion 23 disposed on an upper surface 22u of the power semiconductor element 22, and a bonding wire 27 for connecting another front surface pattern 21 different from the one front surface pattern 21 among the plurality of front surface patterns 21 and the electrode portion 23, in which the electrode portion 23 includes a contact layer 24 formed of a metal and disposed on the upper surface 22u, protective layers 25, 25a, and 25b laminated on the contact layer 24, and a connection layer 26 formed of a metal and laminated on the protective layers 25, 25a, and 25b in a state of being connected to the bonding wire 27, and the protective layers 25, 25a, and 25b include a conductive ceramic having a hardness higher than that of the contact layer 24 and the connection layer 26.

Accordingly, when ultrasonic waves are applied to the electrode portion 23 at the time of wire bonding and pressure due to the ultrasonic waves is applied to the connection layer 26 of the electrode portion 23, the pressure is absorbed by the protective layers 25, 25a, and 25b in the electrode portion 23. In addition, heat conduction from the connection layer 26 to the contact layer 24 can be suppressed as compared with a case where the protective layers 25, 25a, and 25b are formed of, for example, metal.
(2) The substrate 12 for a power module according to a second aspect is the substrate 12 for a power module according to the first aspect, in which the protective layer 25a may include a first metal layer 251 formed of a metal containing Ti and integrally laminated on the contact layer 24, a main body layer 252 formed of a conductive ceramic and integrally laminated on the first metal layer 251, and a second metal layer 253 formed of a metal containing Ti and integrally disposed with the main body layer 252 and the connection layer 26 between the main body layer 252 and the connection layer 26.

Thus, the pressure generated by the ultrasonic waves at the time of wire bonding is absorbed by the second metal layer 253 in the protective layer 25a. The pressure transmitted from the main body layer 252 toward the power semiconductor element 22 is absorbed by the first metal layer 251 in the protective layer 25a.
(3) The substrate 12 for a power module according to a third aspect is the substrate 12 for a power module according to the first aspect, in which the protective layer 25b may include a first protective layer 254 formed of a conductive ceramic and integrally laminated on the contact layer 24, a metal layer 255 formed of a metal containing Ti and integrally laminated on the first protective layer 254, and a second protective layer 256 formed of a conductive ceramic and integrally disposed with the metal layer 255 and the connection layer 26 between the metal layer 255 and the connection layer 26.

Thus, when a pressure generated by ultrasonic waves during wire bonding is applied to the connection layer 26 of the electrode portion 23, the pressure is absorbed by the second protective layer 256 and the metal layer 255. In addition, for example, compared to a case where the protective layer 25b is a single layer, it is possible to further increase the thickness of the protective layer 25b while suppressing the occurrence of deformation such as distortion or bending in the protective layer 25b.
(4) The substrate 12 for a power module according to a fourth aspect is the substrate 12 for a power module according to the first aspect, in which the contact layer 24 may be formed with a thickness L1 of 0.05 to 0.5 μm, and the protective layer 25 may be formed with a thickness L2 of 0.5 to 2 μm.

Accordingly, it is possible to suppress the occurrence of deformation such as distortion or bending in the contact layer 24 and the protective layer 25 while ensuring conductivity between the power semiconductor element 22 and the bonding wire 27.
(5) The substrate 12 for a power module according to a fifth aspect is the substrate 12 for a power module according to the second aspect, in which the contact layer 24 may be formed with a thickness L1 of 0.05 to 0.5 μm, the first metal layer 251 and the second metal layer 253 may be formed with thicknesses L2a and L2c of 0.1 to 0.5 μm, and the main body layer 252 may be formed with a thickness L2b of 0.5 to 2 μm.

Thus, the occurrence of deformation such as distortion in each layer can be suppressed while ensuring conductivity between the power semiconductor element 22 and the bonding wire 27.
(6) A substrate 12 for a power module according to a sixth aspect is the substrate 12 for a power module according to the third aspect, in which the first protective layer 254 and the second protective layer 256 may be formed with thicknesses L2d and L2f of 0.5 to 2 μm, and the metal layer 255 may be formed with a thickness L2e of 0.1 to 0.5 μm.

Thus, the occurrence of deformation such as distortion in each layer can be suppressed while ensuring conductivity between the power semiconductor element 22 and the bonding wire 27.
(7) A substrate 12 for a power module according to a seventh aspect is the substrate 12 for a power module according to any one of the first to sixth aspects, in which the conductive ceramic may be formed of any one of TiB₂, ZrB₂, HfB₂, TiSi₂, and WSi₂.

Accordingly, the above-described operations can be realized with higher accuracy.
(8) The substrate 12 for a power module according to an eighth aspect is the substrate 12 for a power module according to any one of the first to seventh aspects, in which a plurality of the bonding wires 27 may connect the other front surface pattern 21 and the connection layer 26.

### INDUSTRIAL APPLICABILITY

According to the present disclosure, it is possible to provide a substrate for a power module capable of further reducing damage applied to a power semiconductor element during wire bonding.

### REFERENCE SIGNS LIST

1: casing
1a: input side side surface
1b: output side side surface
2: external input conductor
3: capacitor
4: power conversion unit
5: cooler
10: power module
11: base plate
11a: first surface
11b: second surface
12: substrate for power module
13: main terminal portion
13p: P terminal
13n: N terminal
14: output terminal portion
15: reinforcing portion
16: sealing portion
20: insulating plate
20a: front surface
20b: back surface
21: front surface pattern
21a: first front surface pattern
21b: second front surface pattern
21c: third front surface pattern
22: power semiconductor element
22a: first power semiconductor element
22b: second power semiconductor element
22d: lower surface
22u: upper surface
23: electrode portion
24: contact layer
25, 25a, 25b: protective layer
26: connection layer
27: bonding wire
28: back surface pattern
51: base portion
51a: bonding surface
51b: heat dissipation surface
52: heat dissipation fin
100: power conversion device
251: first metal layer
252: main body layer
253: second metal layer
254: first protective layer
255: metal layer
256: second protective layer
G: gap
Rp: potting space
S: bonding material
W: liquid refrigerant

1. A substrate for a power module, comprising:
an insulating plate;
a plurality of front surface patterns disposed on a front surface of the insulating plate;
a power semiconductor element connected to one front surface pattern among the plurality of front surface patterns;
an electrode portion disposed on an upper surface of the power semiconductor element; and
a bonding wire for connecting another front surface pattern different from the one front surface pattern among the plurality of front surface patterns and the electrode portion,
wherein the electrode portion includes
a contact layer formed of a metal and disposed on the upper surface,
a protective layer laminated on the contact layer, and
a connection layer formed of a metal and laminated on the protective layer in a state of being connected to the bonding wire, and
the protective layer includes a conductive ceramic having a hardness higher than that of the contact layer and the connection layer.

2. The substrate for a power module according to claim 1,
wherein the protective layer includes
a first metal layer formed of a metal containing Ti and integrally laminated on the contact layer,
a main body layer formed of a conductive ceramic and integrally laminated on the first metal layer, and
a second metal layer formed of a metal containing Ti and integrally disposed with the main body layer and the connection layer between the main body layer and the connection layer.

3. The substrate for a power module according to claim 1,
wherein the protective layer includes
a first protective layer formed of a conductive ceramic and integrally laminated on the contact layer,
a metal layer formed of a metal containing Ti and integrally laminated on the first protective layer, and
a second protective layer formed of a conductive ceramic and integrally disposed with the metal layer and the connection layer between the metal layer and the connection layer.

4. The substrate for a power module according to claim 1,
wherein the contact layer is formed with a thickness of 0.05 to 0.5 μm, and
the protective layer is formed with a thickness of 0.5 to 2 μm.

5. The substrate for a power module according to claim 2,
wherein the contact layer is formed with a thickness of 0.05 to 0.5 μm,
the first metal layer and the second metal layer are formed with a thickness of 0.1 to 0.5 μm, and
the main body layer is formed with a thickness of 0.5 to 2 μm.

6. The substrate for a power module according to claim 3,
wherein the first protective layer and the second protective layer are formed with a thickness of 0.5 to 2 μm, and
the metal layer is formed with a thickness of 0.1 to 0.5 μm.

7. The substrate for a power module according to claim 1, wherein the conductive ceramic is formed of any one of TiB₂, ZrB₂, HfB₂, TiSi₂, or WSi₂.

8. The substrate for a power module according to claim 1, wherein a plurality of the bonding wires connect the other front surface pattern and the connection layer.
